(19) United States
(12) Patent Application Publication
(10) Pub. No.: US 2018/0294197 A1
(43) Pub. Date: Oct. 11, 2018

(54) SYSTEM DESIGN FOR IN-LINE PARTICLE AND CONTAMINATION METROLOGY FOR SHOWERHEAD AND ELECTRODE PARTS

(71) Applicant: Lam Research Corporation, Fremont, CA (US)

(72) Inventors: Mary Anne PLANO, Mountain View, CA (US); Bhaskar Sompalli, Fremont, CA (US); Ian Scot Latchford, Palo Alto, CA (US)

(21) Appl. No.: 15/945,806

(22) Filed: Apr. 5, 2018

Related U.S. Application Data
(60) Provisional application No. 62/482,642, filed on Apr. 6, 2017.

(51) Int. Cl. H01L 21/66; H01L 21/02; B05B 13/00

(52) U.S. Cl. CPC H01L 22/20; B05B 13/00; H01L 21/02041

(57) ABSTRACT

A method for testing cleanliness of a component of a substrate processing chamber includes loading the component into a vacuum chamber, arranging a test substrate within the vacuum chamber, with the component and the test substrate loaded within the vacuum chamber, providing a purge gas to the vacuum chamber, determining at least one of an amount of particles accumulated on the test substrate and an amount of metal contamination accumulated on the test substrate caused by providing the purge gas to the vacuum chamber, and estimating the cleanliness of the component based on the at least one of the determined amount of particles accumulated on the test substrate and the determined amount of metal contamination accumulated on the test substrate.

### CROSS-REFERENCE TO RELATED APPLICATIONS

This application claims the benefit of U.S. Provisional Application No. 62/482,642, filed on Apr. 6, 2017. This application is related by subject matter to U.S. application Ser. No. 15/782,410, filed Oct. 12, 2017, which claims the benefit of U.S. Provisional Application No. 62/417,529, filed on Nov. 4, 2016 and U.S. Provisional Application No. 62/420,709, filed on Nov. 11, 2016. The entire disclosures of the applications referenced above are incorporated herein by reference.

### FIELD

The present disclosure relates to fabrication of components of vacuum processing systems used for processing substrates.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, rapid thermal processing (RTP), ion implant, physical vapor deposition (PVD), and/or other etch, deposition, or cleaning processes. A substrate may be arranged on a substrate support, such as a pedestal, an electrostatic chuck (ESC), etc. in a processing chamber of the substrate processing system. During processing, gas mixtures including one or more precursors may be introduced into the processing chamber and plasma may be used to initiate chemical reactions.

The processing chamber includes various components including, but not limited to, the substrate support, a gas distribution device (e.g., a showerhead, which may also correspond to an upper electrode), a plasma confinement shroud, etc. The substrate support may include a ceramic layer arranged to support a wafer. For example, the wafer may be clamped to the ceramic layer during processing. The substrate support may include an edge ring arranged around an outer portion (e.g., outside of and/or adjacent to a perimeter) of the substrate support. The edge ring may be provided to confine plasma to a volume above the substrate, protect the substrate support from erosion caused by the plasma, etc. The plasma confinement shroud may be arranged around each of the substrate support and the showerhead to further confine the plasma within the volume above the substrate.

### SUMMARY

A method for testing cleanliness of a component of a substrate processing chamber includes loading the component into a vacuum chamber, arranging a test substrate within the vacuum chamber, with the component and the test substrate loaded within the vacuum chamber, providing a purge gas to the vacuum chamber, determining at least one of an amount of particles accumulated on the test substrate and an amount of metal contamination accumulated on the test substrate caused by providing the purge gas to the vacuum chamber, and estimating the cleanliness of the component based on the at least one of the determined amount of particles accumulated on the test substrate and the determined amount of metal contamination accumulated on the test substrate.

In other features, the component is a showerhead. Loading the component includes connecting an inlet of the showerhead to an inlet of the vacuum chamber in communication with a purge source. Providing the purge gas to the vacuum chamber includes pumping the vacuum chamber down to a first pressure and providing the purge gas until the vacuum chamber is at a second pressure. Providing the purge gas includes repeating pumping the vacuum down to the first pressure and providing the purge gas until the vacuum chamber is at the second pressure two or more times.

In other features, arranging the test substrate within the vacuum chamber includes arranging the substrate on a pedestal below the component. A diameter of the pedestal is less than a diameter of the test substrate. The method further includes arranging a second test substrate within the vacuum chamber and providing the purge gas to the vacuum chamber with the second test substrate arranged within the vacuum chamber. The method further includes arranging the second test substrate within the vacuum chamber and providing the purge gas to the vacuum chamber with the second test substrate arranged within the vacuum chamber in response to the estimated cleanliness of the component.

A system for testing cleanliness of a component of a substrate processing chamber includes a vacuum chamber. An inlet is provided in an upper surface of the vacuum chamber and a pedestal is arranged below the inlet. The inlet is arranged to be in fluid communication with an interior of the component. The inlet is in fluid communication with a purge gas source via a manifold, and the purge gas source is configured to provide a purge gas to the vacuum chamber with a test substrate arranged on the pedestal. A pump is configured to pump down the vacuum chamber to a first pressure prior to the purge gas source providing the purge gas to the vacuum chamber and vent the vacuum chamber subsequent to the purge gas being provided to the vacuum chamber.

In other features, the component is a showerhead of a substrate processing chamber. An inlet of the showerhead is connected to the inlet of the vacuum chamber. A diameter of the pedestal is less than a diameter of the test substrate. At least one of a hanger and a shelf is arranged within the vacuum chamber and the component is supported by the at least one of the hanger and the shelf. A second inlet provided in at least one of the upper surface of the vacuum chamber, a bottom surface of the vacuum chamber, and a sidewall of the vacuum chamber. A process source is in fluid communication with the vacuum chamber. The inlet includes a connector extending through the upper surface of the vacuum chamber.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example processing chamber according to the present disclosure;

FIG. 2 is a functional block diagram of an example part processing system according to the present disclosure;

FIGS. 3A and 3B are example vacuum chambers of a part processing system according to the principles of the present disclosure;

FIG. 4 illustrates steps of an example part processing method according to the principles of the present disclosure;

FIGS. 5A and 5B are example vacuum chambers of a particle and metal contamination checking system according to the principles of the present disclosure; and

FIG. 6 illustrates steps of an example particle and metal contamination checking method according to the principles of the present disclosure.

In the drawings, reference numbers may be reused to identify similar and/or identical elements.

### DETAILED DESCRIPTION

Components arranged within a processing chamber of a substrate processing system include, but are not limited to, a gas distribution device (e.g., a showerhead), a plasma confinement shroud, and/or a substrate support including a baseplate, one or more edge rings, coupling rings, etc. These and other components are fabricated, using various fabrication processes, outside of the processing chamber. Components may also be removed from the processing chamber for repair, cleaning, resurfacing, replacement, etc.

Components within the processing chamber that may affect processing of a substrate may be referred to as critical chamber parts. Accordingly, defects (e.g., particles, nanometer-sized defects, metal contaminants, etc.) associated with the components introduced into the chamber may interfere with processing of the substrate. For example, defects may adhere to components that are fabricated, machined, cleaned, etc. outside of the processing chamber and may therefore be brought into the processing chamber with the components. In particular, defects may adhere to the components due to water remaining on surfaces of the components subsequent to fabrication or cleaning processes (e.g., water remaining after a wet cleaning step, and/or water that is reabsorbed onto and/or otherwise attached to the surfaces after wet cleaning and baking steps). The components may then shed the defects at startup and during processing (e.g., etch, deposition, etc.), degrading startup performance and processing results.

Systems and methods according to the principles of the present invention reduce the amount of defects that attach to the surface of processing chamber components during and subsequent to machining, wet cleaning, and/or other fabrication steps. In example implementations, defects and metal contaminants may be removed from the components by cycle purging using a combination of vacuum pumping, gas purge, and elevated temperatures. Dehydration of part surfaces may aid in defect and metal contamination reduction.

Optionally, a protective coating (e.g., a monolayer coating) may be applied to the surfaces to protect the part from additional water absorption. Example coatings include, but are not limited to, silane coatings, such as an organosilane, hydrophobic coating (e.g., Bis(trimethylsilyl)amine, or hexamethyldisilazane (HMDS)). In one example, the components are baked in a vacuum chamber to remove surface water and defects, and the coating is applied in the same chamber. Accordingly, the coating prevents absorption of water from the atmosphere onto the surfaces of the components after removal from the vacuum chamber and prior to being arranged within the process chamber. In this manner, defects introduced into the process chamber by components are minimized, and pumping of the process chamber to remove water and other materials is reduced. As used herein, the protective coating may be referred to as a coating, layer, and/or film.

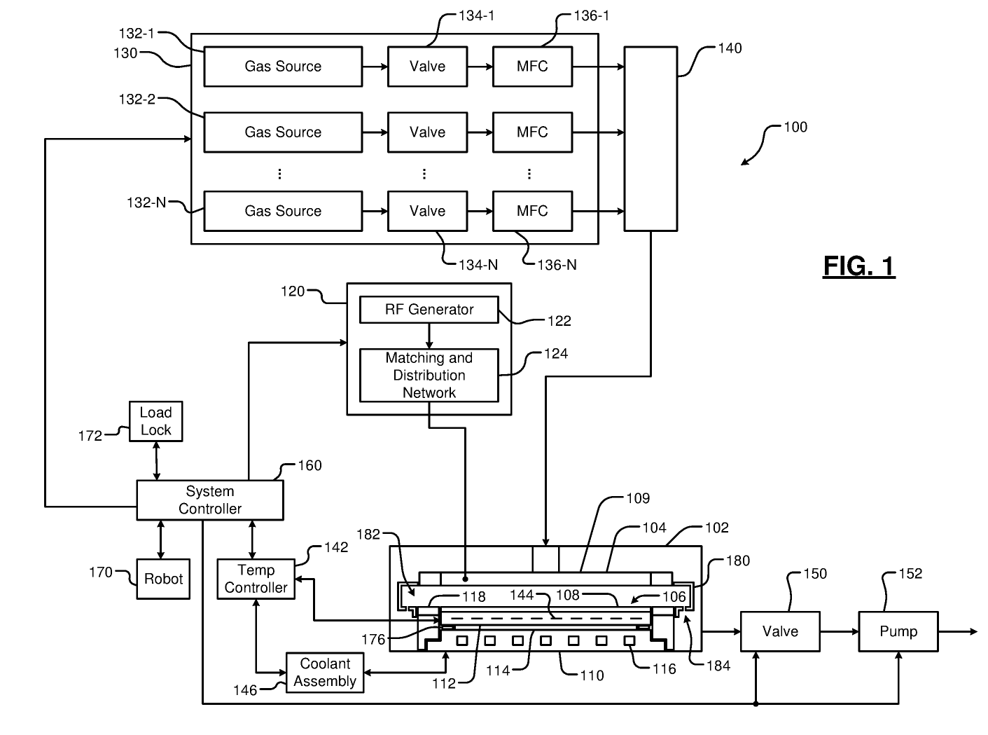

Referring now to FIG. 1, an example substrate processing system 100 is shown to illustrate various types of processing chamber components to be processed using the ultra-low defect part process and in-line particle and metal contamination checking process described below. For example only, the substrate processing system 100 may be used for performing deposition and/or etching using RF plasma and/or other suitable substrate processing. The substrate processing system 100 includes a processing chamber 102 that encloses other components of the substrate processing system 100 and contains the RF plasma. The substrate processing chamber 102 includes an upper electrode 104 and a substrate support 106, such as an electrostatic chuck (ESC). During operation, a substrate 108 is arranged on the substrate support 106. While a specific substrate processing system 100 and chamber 102 are shown as an example, the principles of the present disclosure may be applied to other types of substrate processing systems and chambers, such as a substrate processing system that generates plasma in-situ, that implements remote plasma generation and delivery (e.g., using a plasma tube, a microwave tube), etc.

For example only, the upper electrode 104 may include a gas distribution device such as a showerhead 109 that introduces and distributes process gases. The showerhead 109 may include a stem portion including one end connected to a top surface of the processing chamber. A base portion is generally cylindrical and extends radially outwardly from an opposite end of the stem portion at a location that is spaced from the top surface of the processing chamber. A substrate-facing surface or faceplate of the base portion of the showerhead includes a plurality of holes through which process gas or purge gas flows. Alternately, the upper electrode 104 may include a conducting plate and the process gases may be introduced in another manner.

The substrate support 106 includes a conductive baseplate 110 that acts as a lower electrode. The baseplate 110 supports a ceramic layer 112. In some examples, the ceramic layer 112 may comprise a heating layer, such as a ceramic multi-zone heating plate. A thermal resistance layer 114 (e.g., a bond layer) may be arranged between the ceramic layer 112 and the baseplate 110. The baseplate 110 may include one or more coolant channels 116 for flowing coolant through the baseplate 110. The substrate support 106 may include an edge ring 118 arranged to surround an outer perimeter of the substrate 108.

An RF generating system 120 generates and outputs an RF voltage to one of the upper electrode 104 and the lower electrode (e.g., the baseplate 110 of the substrate support 106). The other one of the upper electrode 104 and the baseplate 110 may be DC grounded, AC grounded or floating. For example only, the RF generating system 120 may include an RF voltage generator 122 that generates the RF voltage that is fed by a matching and distribution network 124 to the upper electrode 104 or the baseplate 110. In other examples, the plasma may be generated inductively or remotely. Although, as shown for example purposes, the RF generating system 120 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

A gas delivery system 130 includes one or more gas sources 132-1, 132-2, . . . , and 132-N (collectively gas sources 132), where N is an integer greater than zero. The gas sources supply one or more gas mixtures. The gas sources may also supply purge gas. Vaporized precursor may also be used. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example only, the output of the manifold 140 is fed to the showerhead 109.

A temperature controller 142 may be connected to a plurality of heating elements, such as thermal control elements (TCEs) 144 arranged in the ceramic layer 112. For example, the heating elements 144 may include, but are not limited to, macro heating elements corresponding to respective zones in a multi-zone heating plate and/or an array of micro heating elements disposed across multiple zones of a multi-zone heating plate. The temperature controller 142 may be used to control the plurality of heating elements 144 to control a temperature of the substrate support 106 and the substrate 108. Each of the heating elements 144 according to the principles of the present disclosure includes a first material having a positive TCR and a second material having a negative TCR as described below in more detail.

The temperature controller 142 may communicate with a coolant assembly 146 to control coolant flow through the channels 116. For example, the coolant assembly 146 may include a coolant pump and reservoir. The temperature controller 142 operates the coolant assembly 146 to selectively flow the coolant through the channels 116 to cool the substrate support 106.

A valve 150 and pump 152 may be used to evacuate reactants from the processing chamber 102. A system controller 160 may be used to control components of the substrate processing system 100. A robot 170 may be used to deliver substrates onto, and remove substrates from, the substrate support 106. For example, the robot 170 may transfer substrates between the substrate support 106 and a load lock 172. Although shown as separate controllers, the temperature controller 142 may be implemented within the system controller 160. In some examples, a protective seal 176 may be provided around a perimeter of the bond layer 114 between the ceramic layer 112 and the baseplate 110.

In some examples, the processing chamber 102 may include a plasma confinement shroud 180, such as a C-shroud. The C-shroud 180 is arranged around the upper electrode 104 and the substrate support 106 to confine plasma within a plasma region 182. In some examples, the C-shroud 180 comprises a semiconductor material, such as silicon carbide (SiC). The C-shroud 180 may include one or more slots 184 arranged to allow gases to flow out of the plasma region 182 to be vented from the plasma chamber 102 via the valve 150 and the pump 152.

Various components of the processing chamber 102 may be treated using an ultra-low defect part process according to the principles of the present disclosure. For example, components processed as described herein may include, but are not limited to, the upper electrode 104, the showerhead 109, the edge ring 118, the plasma confinement shroud 180, any components including silicon, aluminum, and/or quartz, and/or any other components of the processing chamber 102. For example only, the ultra-low defect part process is described below with respect to the processing of a showerhead.

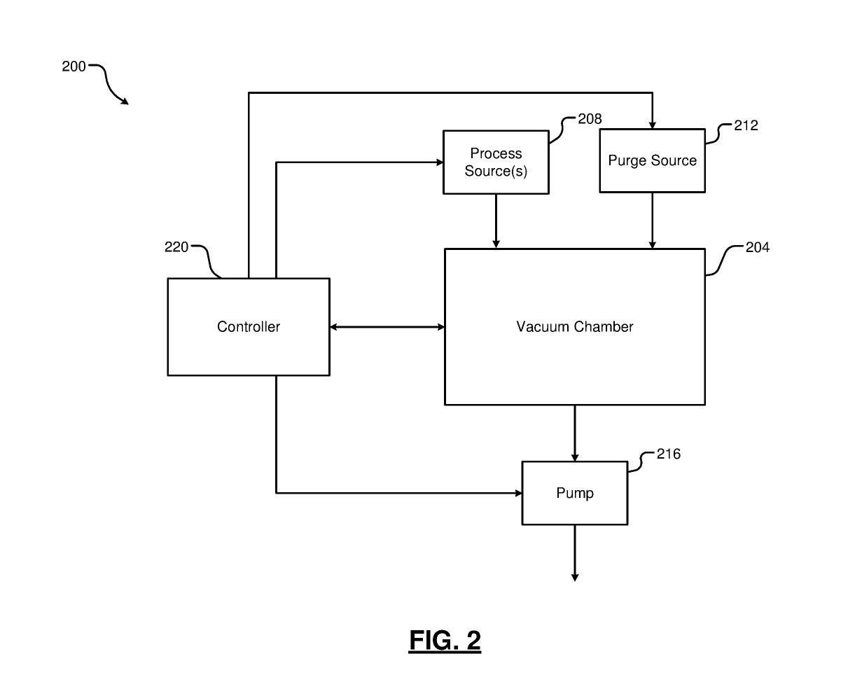

Referring now to FIG. 2, an example part processing system 200 includes a vacuum chamber 204 configured to receive and support a component for various processing steps subsequent to wet cleaning and prior to installation within a substrate processing chamber. For example, the vacuum chamber 204 may correspond to a vacuum oven modified to interface with one or more process sources 208 (i.e., process gas sources), a purge source 212 (i.e., a purge gas source), and a pump 216. In some examples, a controller 220 communicates with the vacuum chamber 204, the process source 208, the purge source 212, and/or the pump 216.

In one example, a component (e.g., a showerhead) is loaded into the vacuum chamber 204. The component may include residual water and associated defects remaining after fabrication and/or wet cleaning and/or production use in a vacuum processing system and/or subsequent exposure to atmosphere. The system 200 performs a vacuum bake step (i.e., a dehydration step) with the component loaded within for a first predetermined period. For example, the vacuum chamber 204 may be maintained at a baking temperature of approximately 200° C. (e.g., between 190 and 210° C.) and between 1 and 760 Torr during the vacuum bake step. In other examples, the baking temperature may be maintained within a range of 180-270° C. or 150-300° C. Accordingly, the vacuum bake step evaporates, and therefore removes, residual water/moisture from the surface of the component. Removing water from the surface of the component inhibits defects from adhering to the component.

The system 200 performs a purge step for a second predetermined period to remove the evaporated water and the defects from the vacuum chamber 204. For example, during purging, the pump 216 is operated to purge the defects from the vacuum chamber 204. A purge gas, such as nitrogen (N2) and/or oxygen (O2), may be provided to the vacuum chamber 204 from the purge source 212 during the purge step. Accordingly, the purge gas is purged from the vacuum chamber 204 along with the defects removed from the surface of the component. In one example, the purge gas may be heated prior to entering the vacuum chamber 204 to maintain the vacuum chamber 204 at the desired temperature. The purge step and the vacuum bake step may be performed simultaneously (i.e., purging is performed continuously during vacuum baking), and/or may at least partially overlap. In another example, the purge step is performed subsequent to the vacuum bake step. In another example, the system 200 cycles alternating purge and vacuum bake steps (e.g., for 2 hours), and/or pulses a plurality of purge steps during an extended vacuum bake step. In this manner, the system 200 generates turbulent flow within the vacuum chamber 204 to facilitate removal of the defects. In other words, the first predetermined period and the second predetermined period may correspond to concurrent periods, overlapping periods, sequential, non-overlapping periods, a plurality of alternating periods, etc.

Subsequent to completion of the vacuum bake step and the purge step, the system 200 may perform a vacuum coating step (i.e., a coating step while the chamber 204 is under vacuum) to apply a coating to the surfaces of the component. In other words, subsequent to vacuum baking the component and purging defects from the component, and with the component still loaded within the vacuum chamber 204, a coating may be applied to the surfaces of the component. For example, various process gases may be provided from the process source(s) 208 to the chamber 204 to apply the coating. With the chamber 204 under vacuum, the provided source fluid or gas vaporizes and fills the chamber 204 to coat all exposed surfaces of the component. In some example, another purge step may be performed subsequent to the vacuum coating step to remove any residual materials from the chamber 204.

The coating comprises a hydrophobic material (e.g., film) that prevents water and associated defects from reabsorbing/reattaching to the surfaces of the component. Accordingly, when the component is removed from the chamber 204 for transfer to a substrate processing chamber, water and associated defects and metal contaminants attaching to the surfaces of the component are minimized. Example coatings include, but are not limited to, silane coatings, such as an organosilane, hydrophobic coating (e.g., Bis(trimethylsilyl)amine, or hexamethyldisilazane (HMDS)).

In some examples, the coating is applied as a monolayer (e.g., a layer having a thickness of 1 atom or 1 molecule of the corresponding material). The coating may be configured to be removed within the substrate processing chamber prior to any processing of a substrate. In other words, the coating may correspond to a sacrificial layer. For example, substrate processing systems may perform a “seasoning” step, prior to processing substrates, when new components are installed. The seasoning step may remove any remaining contaminants and/or defects within the processing chamber subsequent to installation of new components, repairs, etc. In some examples, seasoning includes generating plasma and/or performing other chemical processes to clean, condition, and/or otherwise prepare the processing chamber 204. Accordingly, the seasoning step removes the coating applied by the part processing system 200.

In one example, the chamber 204 may be configured to process a specific component of a substrate processing chamber (e.g., a showerhead). Accordingly, an interior of the chamber 204 may be configured to accommodate that specific component. For example, the interior of the chamber 204 may be sized according to the corresponding component, or may include additional structure configured to support, hang, etc. the component. In other examples, the chamber 204 may be configured to process any of the components of a substrate processing chamber. In some examples, the chamber 204 may be configured to accommodate and process two or more components simultaneously.

The controller 220 may be configured to control the part processing system 200 according to predetermined settings for respective components. For example, the controller 220 may store one or more sets of predetermined settings associated with controlling the part processing system 200, including, but not limited to, control parameters associated with the pump 216 (e.g., on and off periods), the process source 208 (e.g. on and off periods, flow rates, etc.), the purge source 212 (e.g. on and off periods, flow rates, etc.), and heating elements for temperature control. Any control parameters may also be manually input by a user. In examples where the chamber 204 is configured to process two or more types of components of a substrate processing system, the controller 220 may store a different set of predetermined settings for each component. For example, a showerhead may have a first associated set of settings, while an edge ring may have a second associated set of settings. The controller 220 may be configured to automatically select the appropriate set of predetermined settings based on receiving (e.g., from a user) an indication of which component is loaded within the chamber 204 for processing.

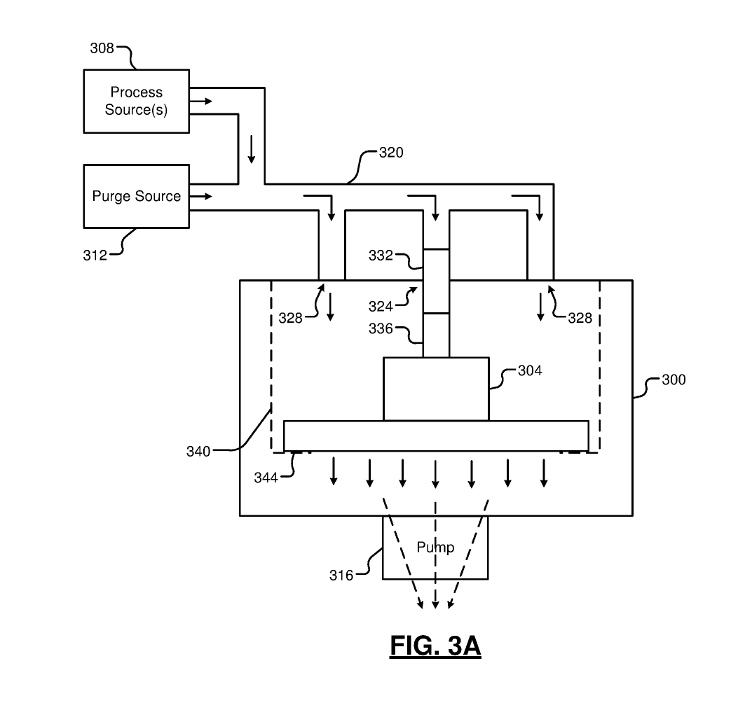

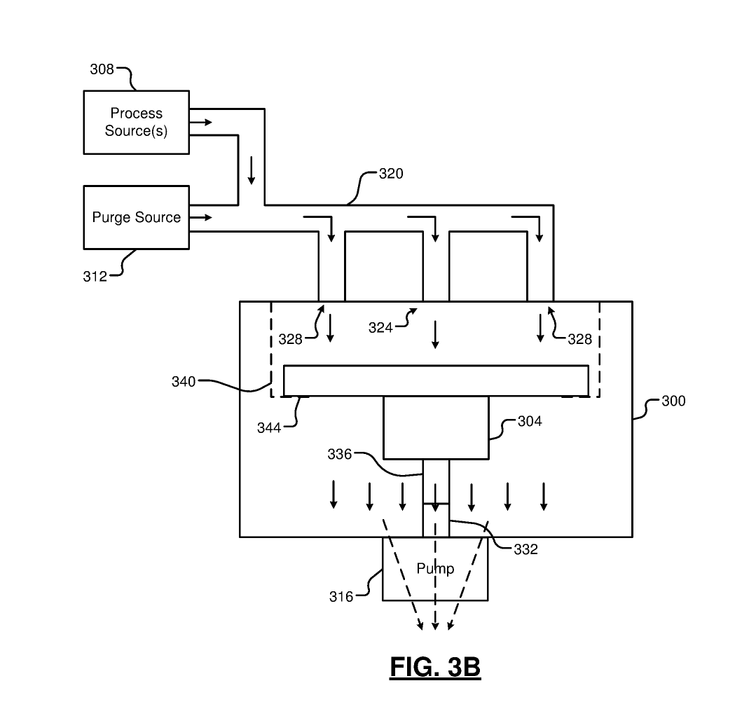

Referring now to FIGS. 3A and 3B, an example vacuum chamber 300 configured for processing a showerhead 304 is shown. In FIG. 3A, the showerhead 304 is shown arranged in the vacuum chamber 300 in a first configuration (e.g., an upright configuration). Conversely, in FIG. 3B, the showerhead 304 is shown arranged in the vacuum chamber 300 in a second configuration (e.g., an upside down configuration). The chamber 300 interfaces with a process source(s) 308, a purge source 312, and a pump 316 as described above with respect to FIG. 2. For example, the process source 308 and the purge source 312 are in fluid communication with an interior of the chamber 300 via a manifold 320 and various inlets 324 and 328 arranged in an upper surface of the chamber 300. Although, as shown, the process source 308 and the purge source 312 share the same manifold 320 and inlets 324 and 328, the process source 308 and the purge source 312 may each use respective, independent manifolds and inlets in other examples.

The inlets 328 may include one or more inlets 328 arranged above and around a perimeter of the showerhead 304. Although shown arranged in the upper surface of the chamber 300, in other examples the inlets 328 may be arranged in sidewalls of the chamber 300, in a bottom surface of the chamber 300, etc. depending on a size, shape, configuration, etc. of the showerhead or other component being processed within the chamber 300. Conversely, the inlet 324 is arranged to be in fluid communication with an interior of the showerhead 304. For example, in the configuration shown in FIG. 3A, the inlet 324 may include a connector 332 extending through the upper surface of the chamber 300 and connecting to each of the manifold 320 and an inlet 336 of the showerhead 304. Conversely, in the configuration shown in FIG. 3B, the connecter 332 may be arranged to connect the inlet 336 of the showerhead 304 to an inlet of the pump 316. For example only, the connector 332 may correspond to an ultra-Torr fitting.

The chamber 300 may include a support structure, such as a hanger or shelf 340, arranged to support the showerhead 304 during processing. For example, the shelf 340 may be connected to the upper surface of the chamber 300 and extend downward into the interior of the chamber 300 to provide a surface 344 positioned to support the showerhead 304. Chambers configured for processing other types of components may include suitable respective support structures. In some examples, the chamber 300 may also be configured to perform a wet cleaning step prior to the part processing steps according to the principles of the present disclosure.

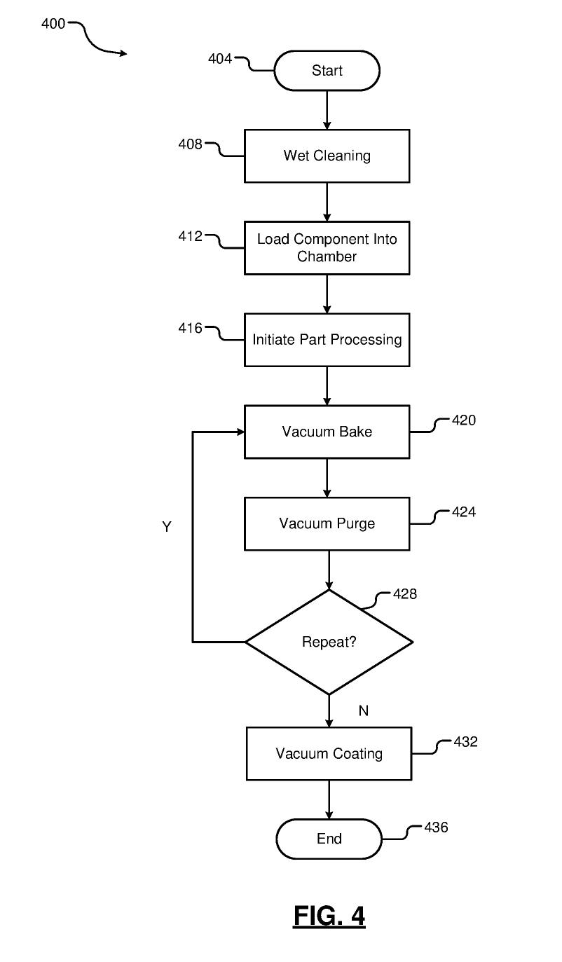

Referring now to FIG. 4, an example part processing method 400 begins at 404. At 408, the method 400 performs a wet cleaning (or another post-fabrication step, pre on a component (e.g., a showerhead) of a substrate processing chamber. At 412, the showerhead is loaded into a vacuum chamber according to the principles of the present disclosure. For example, the showerhead may be loading into a vacuum chamber configured specifically for processing showerheads, such as the vacuum chamber 300 described in FIGS. 3A and 3B.

At 416, a user initiates part processing. In some examples, the user may simply provide an input to initiate the part processing (e.g., via an interface of the controller 220). In other examples, the user may be required to input control parameters, information about the component being processed, etc. The user may be prompted to provide the inputs, and/or may manually input control parameters prior to or subsequent to each step of the method 400 (e.g., to initiate and terminate each step).

At 420, the method 400 performs a vacuum bake step. At 424, the method 400 performs a vacuum purge step. At 428, the method 400 determines whether to repeat vacuum baking and purging. For example, repeating the vacuum baking and purging may correspond to cycling alternating pulses of baking and purging as described above with respect to FIG. 2. Further, although illustrated as separate steps, the vacuum baking and purging shown at 420 and 424 may at least partially overlap such that purging is performed during at least a portion of the vacuum baking. For example, the purging may by pulsed (i.e., cycled between purging and not purging) during a continuous vacuum baking step (i.e., without vacuum baking being interrupted or paused).

If the result of 428 is true, the method 400 continues to 420. If false, the method 400 continues to 432. At 436, the method 400 may apply a vacuum coating to the showerhead. The method 400 ends at 436.

An example part processing system according to the principles of the present disclosure may further implement in-line particle and metal contamination checking subsequent to cleaning steps. For example, in cleaning procedures for components such as showerheads, electrodes, etc., it may be difficult to determine amounts of particulates or metal contamination remaining on the component until the part is installed in the processing chamber and initial processing steps are performed.

In some systems, the processing chamber is pumped down with the component installed, and one or more processing steps are performed with a seasoning or test substrate present in the chamber. The test substrate may then be examined to estimate levels of particle and metal contamination within the chamber. However, this method increases manufacturing time and costs, and it may be difficult to determine whether the contamination was caused by the new component or other structures within the chamber. Further, the cleanliness of the components may not be determined until after the component is provided to an end user or customer and installed in a substrate processing system. Accordingly, the manufacturer is not able to accurately determine the cleanliness of the component prior to delivery and installation.

In-line particle and metal contamination checking systems and methods according to the principles of the present disclosure determine the amount of particles and metal contamination given off by the component itself during the cleaning process. For example, the particle and metal contamination checking as described herein may be performed in a vacuum oven or any other suitable vacuum chamber, such as a chamber similar to the vacuum chamber 300 and/or in a separate chamber subsequent to the steps performed in the vacuum chamber 300.

In one example, a purge gas source is coupled to an inlet of the component within the chamber and a test substrate (e.g., a particle grade substrate) is arranged under the component. An inert purge gas such as nitrogen is pumped through the component. Accordingly, any particles and metal contamination emanating from the component as a result of the purging are collected on the test substrate. The test substrate can then be analyzed using any suitable substrate analysis technique to determine a total particle count and elemental composition of the particles, and thereby estimate an amount of contaminants emanating from the component itself. Metal contamination emanating from the test part can also be determined by analyzing the elemental components collected from the substrate surface area.

In this manner, the in-line particle and metal contamination checking systems and methods improve manufacturing efficiency by eliminating the need to install new components in substrate processing systems prior to analyzing component cleanliness. Further, quality control may be improved by verifying particle counts and metal contamination levels prior to delivering and installing components.

In one example, a vacuum chamber modified to implement particle checking and metal contamination testing may be provided to an entity (e.g., a vendor or other third party) performing final cleaning procedures on components prior to delivery to an end user. Cleaned components may then be installed in the vacuum chamber and, in some examples, a heat treatment process may be performed. A test substrate is then arranged in the chamber and the chamber is pumped down (e.g., to a pressure less than 50 Torr). An inert purge gas is provided to the chamber through an inlet of the component until the pressure increases to a desired amount (e.g., 500 Torr). The chamber may be pumped down and purged in this manner two or more times and the chamber is then vented. In other examples, the inert purge gas may be provided through the component for a predetermined period. Parameters such as flow rates, chamber pressures, type of gas, chamber temperature, etc. may be adjusted according to a type of component being tested.

The test substrate is then removed from the chamber for evaluation. For example, the test substrate may be transferred via a transfer robot to a metrology system to evaluate the particle count and metal contamination of the test substrate and estimate the cleanliness of the component.

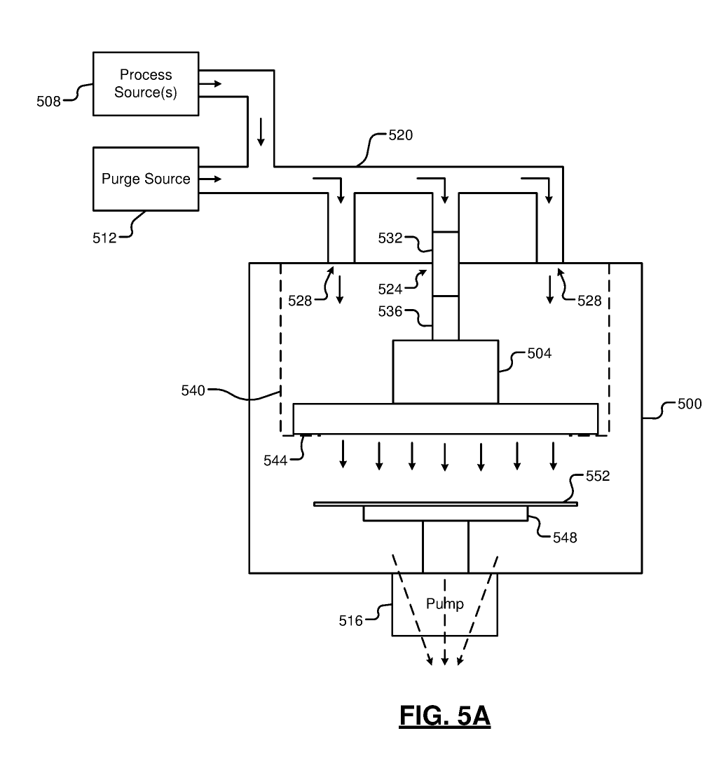

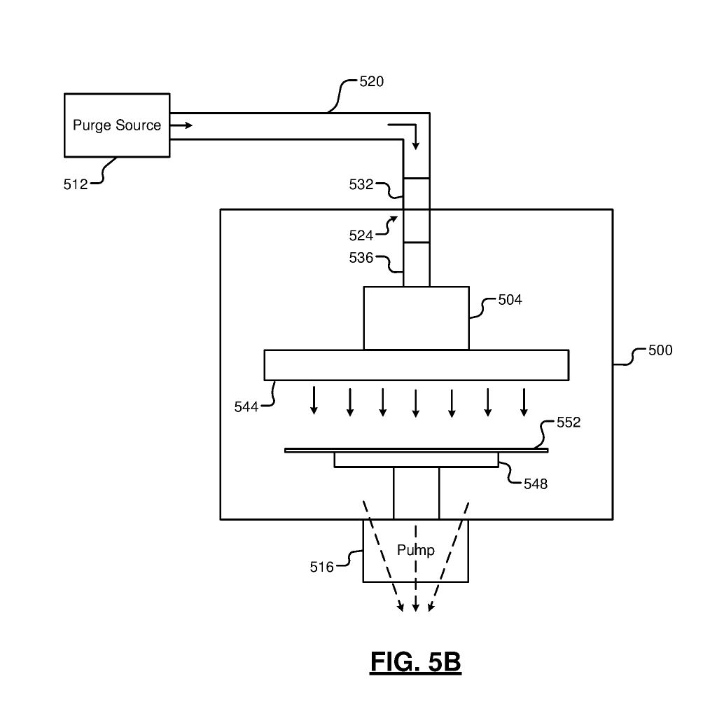

Referring now to FIGS. 5A and 5B, an example vacuum chamber 500 modified to implement in-line particle and metal contamination checking systems and methods according to the present disclosure is shown. Although the vacuum chamber 500 as shown in FIG. 5B is otherwise analogous to the vacuum chamber 300 shown in FIG. 3A, the vacuum chamber 500 may have other suitable configurations. For example, the vacuum chamber 500 may further correspond to a vacuum oven (i.e., the vacuum chamber 500 may be configured to perform heat treatment or other functions), or the vacuum chamber 500 may not be configured to perform vacuum oven functions.

In FIGS. 5A and 5B, a showerhead 504 is shown arranged in the vacuum chamber 500 in a first configuration (e.g., an upright configuration). In other examples, the showerhead 504 may be arranged in a second configuration (e.g., an upside down configuration as shown in FIG. 3B). The chamber 500 shown in FIG. 5A interfaces with a process source(s) 508, a purge source 512, and a pump 516. For example, the process source 508 and the purge source 512 are in fluid communication with an interior of the chamber 500 via a manifold 520 and various inlets 524 and 528 arranged in an upper surface of the chamber 500. Although, as shown, the process source 508 and the purge source 512 share the same manifold 520 and inlets 524 and 528, the process source 508 and the purge source 512 may each use respective, independent manifolds and inlets in other examples.

In other examples, the chamber 500 may not be connected to the process source 508. For example, in some examples the chamber 500 may not be configured to perform vacuum oven functions or vacuum coating functions. In other words, as shown in FIG. 5A, it may be assumed that the vacuum chamber 500 performs vacuum coating, baking, etc. on the showerhead 504 prior to particle and metal contamination checking steps. However, in other examples, vacuum coating and baking steps may be performed in a different chamber prior to transferring the showerhead to the chamber 500 for particle and metal contamination checking. For example, FIG. 5B shows the chamber 500 configured only to perform particle and metal contamination checking. Accordingly, in FIG. 5B, the chamber 500 is shown connected only to the purge source 512 and the process source 508 is omitted.

The inlets 528 may include one or more inlets 528 arranged above and around a perimeter of the showerhead 504 as shown in FIG. 5A. Although shown arranged in the upper surface of the chamber 500, in other examples the inlets 528 may be arranged in sidewalls of the chamber 500, in a bottom surface of the chamber 500, etc. depending on a size, shape, configuration, etc. of the showerhead or other component being processed within the chamber 500. Conversely, the inlet 524 is arranged to be in fluid communication with an interior of the showerhead 504. For example, the inlet 524 may include a connector 532 extending through the upper surface of the chamber 500 and connecting to each of the manifold 520 and an inlet 536 of the showerhead 504. For example only, the connector 532 may correspond to an ultra-Torr fitting. The chamber 500 shown in FIG. 5A includes the inlets 528. Conversely, the inlets 528 are omitted in the configuration shown in FIG. 5B and only the inlet 524 is connected to the showerhead 504.

In some examples, the chamber 500 may include a support structure, such as a hanger or shelf 540, arranged to support the showerhead 504 during processing as shown in FIG. 5A. For example, the shelf 540 may be connected to the upper surface of the chamber 500 and extend downward into the interior of the chamber 500 to provide a surface 544 positioned to support the showerhead 504. In other examples, the shelf 540 may be omitted and the showerhead 504 may instead be supported via the connection between the inlet 536 of the showerhead 504 and the connector 532 as shown in FIG. 5B. Chambers configured for processing other types of components may include suitable respective support structures.

The chamber 500 includes a pedestal 548 arranged below the showerhead 504. For example, the pedestal 548 may be approximately centered within the chamber 500 below the inlet 524. The pedestal 548 is configured to support a test substrate 552. For example, the test substrate 552 may correspond to a silicon particle substrate representative of substrates processed in a substrate processing system where the showerhead 504 will be installed. The pedestal 548 is positioned such that the substrate 552 is arranged in a same location relative to the showerhead 504 as a substrate being processed in a substrate processing chamber. For example, the pedestal 548 is approximately centered beneath the showerhead 504. Further, a height of the pedestal 548 is such that a distance between the showerhead 504 and the substrate 552 is the same as a distance between the showerhead 504 and a substrate in a substrate processing chamber. In this manner, particles and metal contaminants collected on the substrate 552 resulting from purging the chamber 500 will be representative of similar exposure of a substrate in a substrate processing chamber.

As shown, a diameter of the pedestal 548 is less than a diameter of the substrate 552. In other examples, the pedestal 548 may be configured so support a substrate support assembly (such as an ESC). For example, components such as an ESC or other electrode, an edge ring, etc. may be installed on the pedestal 548 to test cleanliness of those components in a similar manner. For example only, only one component (e.g., the showerhead 504, an ESC, an edge ring, etc.) may be installed within the chamber 500 for a given test substrate. Accordingly, multiple test substrates may be used to perform particle and metal contamination checking on respective components. As shown, the pump 516 is arranged below the pedestal 548.

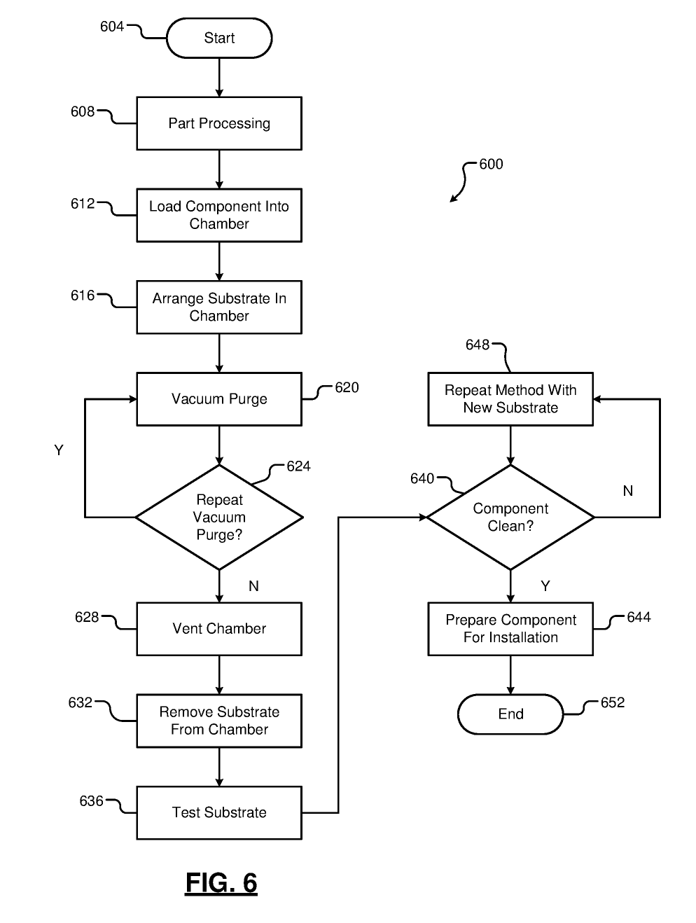

Referring now to FIG. 6, an example particle and metal contamination checking method 600 begins at 604. At 608, the method 600 performs part processing on a component (e.g., a showerhead) of a substrate processing chamber. For example, the part processing may include, but is not limited to, part processing steps such as wet cleaning, vacuum baking, vacuum purging, vacuum coating, etc. as described in the method 400 as described above and in FIG. 4. For example only, one or more of the vacuum baking, vacuum purging, vacuum coating, etc. may be performed in the chamber 500 as shown in FIG. 5A or may be performed in one or more separate chambers.

At 612, the showerhead is loaded into a vacuum chamber configured to perform particle and metal contamination checking according to the principles of the present disclosure. For example, if the vacuum chamber 500 shown in FIG. 5A was used to perform a last one of the part processing steps at 608, the showerhead may simply remain within the same chamber 500. Conversely, if the part processing steps were performed in a separate chamber, the showerhead may then be loaded into the vacuum chamber 500 as described in one of FIGS. 5A and 5B.

At 616, a test substrate is arranged on a pedestal in the vacuum chamber 500. For example, as shown in FIGS. 5A and 5B, the test substrate 552 is arranged on the pedestal 548 below the showerhead 504. At 620, a vacuum purge is performed. In some examples, a user may simply provide an input to initiate the vacuum purge (e.g., via an interface of the controller 220). In other examples, the user may be required to input control parameters, information about the component being processed, etc. The user may be prompted to provide the inputs, and/or may manually input control parameters prior to or subsequent to each step of the method 600 (e.g., to initiate and terminate each step). For example, the vacuum purge may include pumping down the chamber 500 (e.g., to a first pressure less than 50 Torr) and then providing an inert purge gas through the inlet 324 and/or inlets 328 for a predetermined period until the pressure increases to a desired second pressure (e.g., 500 Torr).

At 624, the method 600 determines whether to repeat the vacuum purge. For example, repeating the vacuum purge may correspond to performing two or more separate purging steps. In other examples, the inert purge gas may be provided for only a single predetermined period. If the result of 624 is true, the method 600 continues to 620. If false, the method 600 continues to 628. At 628, the chamber 500 is vented.

At 632, the test substrate is removed from the chamber 500. At 636, the test substrate is analyzed to determine the cleanliness of the component installed in the chamber 500. For example, the substrate may be analyzed using any suitable technique to estimate a particle count and metal contamination on the substrate. At 640, the method 600 determines whether the component is clean based on the estimates. For example, the user may determine whether the particle count is below a predetermined threshold associated with the component or the user may determine whether the contamination of a particular metal is below a predetermined threshold. If true, the method 600 continues to 644. If false, the method continues to 648.

At 644, the component is removed from the chamber 500 and prepared for installation in a substrate processing system. For example, the component may be removed and installed directly into a substrate processing system, prepared for shipping to an end user for installation, etc. At 648, the method 600 (e.g., steps 616 through 640) may be repeated for the same component and a new test substrate within the chamber 500. The method 600 ends at 652.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A method for testing cleanliness of a component of a substrate processing chamber, the method comprising:
loading the component into a vacuum chamber;
arranging a test substrate within the vacuum chamber;
with the component and the test substrate loaded within the vacuum chamber, providing a purge gas to the vacuum chamber;
determining at least one of an amount of particles accumulated on the test substrate and an amount of metal contaminants accumulated on the test substrate caused by providing the purge gas to the vacuum chamber; and
estimating the cleanliness of the component based on the at least one of the determined amount of particles accumulated on the test substrate and the determined amount of metal contamination accumulated on the test substrate.

2. The method of claim 1, wherein the component is a showerhead.

3. The method of claim 2, wherein loading the component includes connecting an inlet of the showerhead to an inlet of the vacuum chamber in communication with a purge source.

4. The method of claim 1, wherein providing the purge gas to the vacuum chamber includes (i) pumping the vacuum chamber down to a first pressure and (ii) providing the purge gas until the vacuum chamber is at a second pressure.

5. The method of claim 4, wherein providing the purge gas includes repeating (i) and (ii) two or more times.

6. The method of claim 1, wherein arranging the test substrate within the vacuum chamber includes arranging the substrate on a pedestal below the component.

7. The method of claim 6, wherein a diameter of the pedestal is less than a diameter of the test substrate.

8. The method of claim 1, further comprising (i) arranging a second test substrate within the vacuum chamber and (ii) providing the purge gas to the vacuum chamber with the second test substrate arranged within the vacuum chamber.

9. The method of claim 8, further comprising performing (i) and (ii) in response to the estimated cleanliness of the component.

10. A system for testing cleanliness of a component of a substrate processing chamber, the system comprising:
a vacuum chamber, wherein the vacuum chamber includes
an inlet provided in an upper surface of the vacuum chamber, wherein the inlet is arranged to be in fluid communication with an interior of the component, and
a pedestal arranged below the inlet;
a purge gas source, wherein the inlet is in fluid communication with the purge gas source via a manifold, and wherein the purge gas source is configured to provide a purge gas to the vacuum chamber with a test substrate arranged on the pedestal; and
a pump configured to (i) pump down the vacuum chamber to a first pressure prior to the purge gas source providing the purge gas to the vacuum chamber and (ii) vent the vacuum chamber subsequent to the purge gas being provided to the vacuum chamber.

11. The system of claim 10, wherein the component is a showerhead of a substrate processing chamber.

12. The system of claim 11, wherein an inlet of the showerhead is connected to the inlet of the vacuum chamber.

13. The system of claim 10, wherein a diameter of the pedestal is less than a diameter of the test substrate.

14. The system of claim 10, further comprising at least one of a hanger and a shelf within the vacuum chamber, wherein the component is supported by the at least one of the hanger and the shelf.

15. The system of claim 10, further comprising a second inlet provided in at least one of the upper surface of the vacuum chamber, a bottom surface of the vacuum chamber, and a sidewall of the vacuum chamber.

16. The system of claim 10, further comprising a process source in fluid communication with the vacuum chamber.

17. The system of claim 10, wherein the inlet includes a connector extending through the upper surface of the vacuum chamber.
